(19) United States
(12) Patent Application Publication
(10) Pub. No.: US 2020/0169194 A1
(43) Pub. Date: May 28, 2020

(54) POWER GENERATION SWITCH

(71) Applicant: Panasonic Intellectual Property Management Co., Ltd., Osaka (JP)

(72) Inventor: TAKAYA NAKAMURA, Osaka (JP)

(21) Appl. No.: 16/637,014

(22) PCT Filed: Jul. 19, 2018
(86) PCT No.: PCT/JP2018/027020

§ 371 Date: Feb. 6, 2020

(30) Foreign Application Priority Data
Sep. 29, 2017 (JP) 2017-189594

(51) Int. Cl. H02N 2/18; H01L 41/113; H01L 41/053

(52) U.S. Cl. CPC H02N 2/186; H01L 41/0536; H01L 41/1136

(57) ABSTRACT

This power generation switch includes: an arm unit including at least a part that rotates toward an area in the Z-axis direction; and a power generation device which generates electric power through rotation of the arm unit. The power generation device includes: a magnet holding unit which moves in the Z-axis direction through rotation of the arm unit and includes a magnet extending in the X-axis direction; a holder portion located in the negative direction of the Y-axis relative to the magnet; and a plate-shaped power generation portion which includes a free end portion that is placed in the state of attraction to the magnet and the state of release from the state of attraction and a fixed portion that is fixed to the holder portion, and generates electric power by free vibrations of the free end portion. The magnet holding unit is rotatably held by the arm unit.

### TECHNICAL FIELD

The present disclosure relates to power generation switches.

### BACKGROUND ART

Conventionally, regarding a signal generation device such as a switch that is capable of remotely controlling an electrical device, providing a power generation device including an actuator (power generation portion) in the signal generation device in order to improve the usability of the signal generation device has been proposed (for example, Patent Literature (PTL) 1).

The signal generation device (power generation switch) disclosed in PTL 1 includes: an actuator (power generation portion) including a piezoelectric element and having a cantilever structure; and a switch (arm unit) having an L-shape in a cross-sectional view. When the switch is pressed, the actuator is bent by the switch and a free end of the actuator coming into contact with each other, and separation of the switch from the actuator allows the actuator to start free vibrations, resulting in generation of a voltage due to the piezoelectric effect. Thus, the signal generation device that does not require batteries is provided.

### CITATION LIST

### Patent Literature

PTL 1: Unexamined Japanese Patent Publication No. 2004-201376

### SUMMARY OF THE INVENTION

A power generation switch according to one aspect of the present disclosure includes: a moving unit including at least a part that moves in a first direction; and a power generation device which generates electric power through movement of the moving unit. The power generation device includes: an attracting unit which moves in the first direction through the movement of the moving unit and includes a magnet extending in a second direction perpendicular to the first direction; a holder portion located in a third direction perpendicular to the second direction relative to the magnet; and a plate-shaped power generation portion which includes (i) a free end portion that is placed in a state of attraction to the magnet and a state of release from the state of attraction and (ii) a fixed portion that is fixed to the holder portion, and generates electric power by free vibrations of the free end portion. The attracting unit is rotatably held by the moving unit.

### BRIEF DESCRIPTION OF THE DRAWINGS

FIG. 1 is a perspective view illustrating the button-unit-side external appearance of a power generation switch according to an exemplary embodiment.

FIG. 2 is a perspective view illustrating the casing-unit-side external appearance of a power generation switch according to an exemplary embodiment.

FIG. 3 is a perspective view illustrating the configuration of a power generation switch according to an exemplary embodiment without a button unit and a casing unit in FIG. 1.

FIG. 4 is an exploded perspective view illustrating the configuration of a power generation switch according to an exemplary embodiment without a button unit and a casing unit in FIG. 1.

FIG. 5 is an exploded perspective view illustrating the configuration of a power generation device according to an exemplary embodiment.

FIG. 6 is a partial cross-sectional view of a power generation portion according to an exemplary embodiment, taken along line VI-VI in FIG. 5.

FIG. 7 is an exploded perspective view illustrating the configuration of a vibration generation unit according to an exemplary embodiment.

FIG. 8 is a perspective view illustrating the configuration of an arm unit according to an exemplary embodiment.

FIG. 9 is a diagram illustrating the configuration of a magnet holding unit according to an exemplary embodiment.

FIG. 10 is a partial cross-sectional view of a vibration generation unit according to an exemplary embodiment, taken along line X-X in FIG. 4.

FIG. 11 is a partial cross-sectional view of a vibration generation unit according to an exemplary embodiment, taken along line XI-XI in FIG. 4.

FIG. 12 is a schematic diagram illustrating the state of a vibration generation unit and the state of a power generation portion before and after operation of a button unit according to an exemplary embodiment.

FIG. 13 is a schematic diagram illustrating another example of the state of a vibration generation unit before and after operation of a button unit according to an exemplary embodiment.

### DESCRIPTION OF EMBODIMENTS

In PTL 1 described above, the switch may fail to be substantially evenly pushed down depending on the position at which the switch is pressed in the width direction of the switch (in other words, in the depth direction with respect to a cross-section). For example, when one end portion of the switch in the width direction is pressed, there are cases where one end portion pushed deeper than the other end portion. In this case, it is difficult for the switch to cause the actuator to be evenly bent, resulting in a reduction in the efficiency of power generation. In other words, there is the problem of low operability due to limitations to the position in the width direction of the switch at which the switch is pressed in such a manner that the switch is substantially evenly pressed down. In particular, a power generation switch the orientation of which is not fixed, such as a portable power generation switch, has low operability.

Thus, an object of the present disclosure is to provide a power generation switch having improved operability.

### Outline of Present Disclosure

In order to achieve the aforementioned object, a power generation switch according to one aspect of the present disclosure includes: a moving unit including at least a part that moves in a first direction; and a power generation device which generates electric power through movement of the moving unit. The power generation device includes: an attracting unit which moves in the first direction through the movement of the moving unit and includes a magnet extending in a second direction perpendicular to the first direction; a holder portion located in a third direction perpendicular to the second direction relative to the magnet; and a plate-shaped power generation portion which includes (i) a free end portion that is placed in a state of attraction to the magnet and a state of release from the state of attraction and (ii) a fixed portion that is fixed to the holder portion, and generates electric power by free vibrations of the free end portion. The attracting unit is rotatably held by the moving unit.

Thus, when the power generation switch is pressed down, the moving unit moves in the first direction. For example, when pressure applied to the moving unit is out of balance, the moving unit is tilted and in this state moves in the first direction. On the other hand, the attracting unit is held in such a manner as to be rotatable around the moving unit, and therefore the tilt of the attracting unit that occurs due to the tilt of the moving unit can be reduced. In other words, even when the moving unit is tilted, there can be attraction (i.e., the area of contact) between the power generation portion and the magnet. This enables the power generation switch to stably generate electric power, resulting in improved operability.

Furthermore, a rotation axis of the attracting unit may be parallel to the third direction.

With this, when the moving unit is tilted, the attracting unit can rotate around a line parallel to the third direction as the rotation axis, with respect to the moving unit. In other words, the attracting unit can reduce tilting of the power generation portion around a line parallel to the third direction as an axis. This further enables the power generation switch to stably generate electric power.

Furthermore, the moving unit may include a first main surface portion extending in the second direction, the attracting unit may include a second main surface portion disposed facing the first main surface portion and extending in the second direction, the attracting unit may include a first shaft portion extending along the rotation axis and at least partially protruding from the second main surface portion toward the first main surface portion, and the moving unit may include an insertion portion into which the first shaft portion is inserted.

Thus, the use of the first shaft portion as the rotation axis allows the attracting unit to easily rotate. Accordingly, the operability of the power generation switch further improves.

Furthermore, the moving unit may include a first main surface portion extending in the second direction, the attracting unit may include a second main surface portion disposed facing the first main surface portion and extending in the second direction, the moving unit may include a first shaft portion extending along the rotation axis and at least partially protruding from the first main surface portion toward the second main surface portion, and the attracting unit may include an insertion portion into which the first shaft portion is inserted.

Thus, the use of the first shaft portion as the rotation axis allows the attracting unit to easily rotate. Accordingly, the operability of the power generation switch further improves.

Furthermore, the insertion portion may be configured to allow the first shaft portion to move inside the insertion portion in the first direction.

With this, the area of contact between the insertion portion and the first shaft portion can be reduced, and thus it is possible to reduce the resistance force due to friction that is applied to the first shaft portion upon movement of the first shaft portion relative to the moving unit. In other words, it is possible to reduce damage to the first shaft portion and keep the first shaft portion from following the tilting of the moving unit. Accordingly, the operability of the power generation switch further improves.

Furthermore, the first shaft portion may include a cutout portion obtained by cutting off an end of the first shaft portion that faces the insertion portion when viewed in the second direction.

With this, the first shaft potion can be easily inserted into the insertion portion, and thus the workability for inserting the first shaft portion into the insertion portion improves.

Furthermore, the moving unit may include: a first end portion pivoted on a second shaft portion; and a second end portion which moves in the first direction by rotation.

This allows the power generation switch to be also applied to a power generation switch in which the power generation portion is bent through rotation of the moving unit to generate electric power.

Furthermore, the power generation portion may include two piezoelectric elements and a metal plate, and the two piezoelectric elements may be disposed at opposite sides of the metal plate.

With this, the amount of electric power that is generated by free vibrations of the power generation portion is greater than that in the case where there is one piezoelectric element.

Hereinafter, exemplary embodiments will be described in detail with reference to the drawings as necessary. However, there are instances where overly detailed description is omitted. For example, detailed description of well-known matter, overlapping description of substantially identical elements, etc., may be omitted. This is to prevent the subsequent description from becoming unnecessarily redundant, and thus facilitate understanding by a person having ordinary skill in the art. Note that the respective figures are schematic diagrams and are not necessarily precise illustrations.

Furthermore, there are cases where the drawings used in the description in the following exemplary embodiments illustrate coordinate axes. The negative side of the Z-axis indicates the side on which a mounting surface is located, and the positive side of the Z-axis indicates the side on which an operating surface is located. The X-axis direction and the Y-axis direction are orthogonal to each other in a plane perpendicular to the Z-axis direction. The XY plane is parallel to a top plate included in the power generation switch. For example, in the following exemplary embodiments, the “plan view” means viewing in the Z-axis direction.

The term “substantially XX” indicates something that is essentially considered to be XX; for example, a “substantially rectangular shape” means not only the shape of a perfect rectangle, but also any other shapes that are essentially considered to be rectangular.

### Exemplary Embodiment

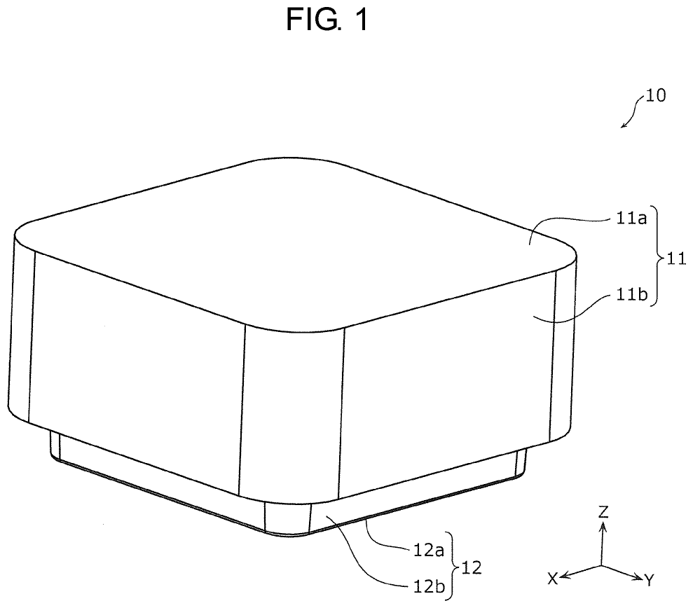

Hereinafter, power generation switch 10 according to the present exemplary embodiment will be described with reference to FIG. 1 to FIG. 13.

### [1. Overall Configuration of Power Generation Switch]

First, the configuration of power generation switch 10 according to the present exemplary embodiment will be described with reference to FIG. 1 to FIG. 9.

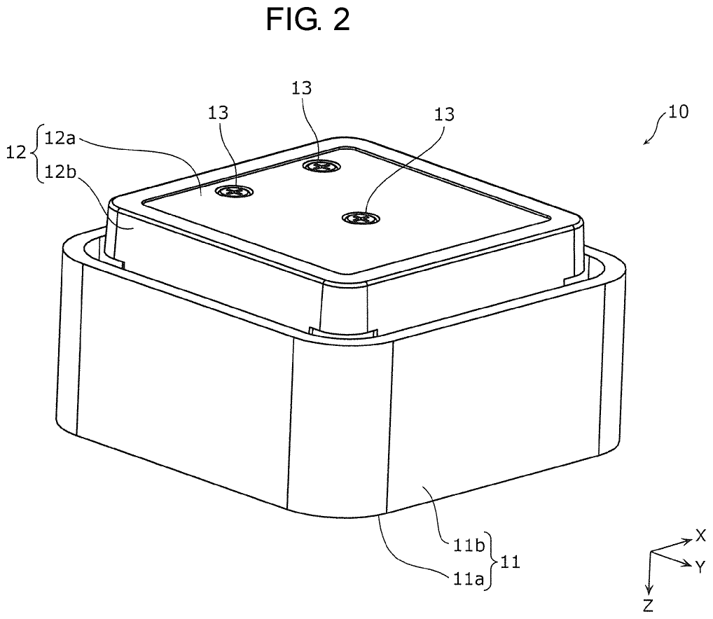

FIG. 1 is a perspective view illustrating the button-unit-11-side external appearance of power generation switch 10 according to the present exemplary embodiment. FIG. 2 is a perspective view illustrating the casing-unit-12-side external appearance of power generation switch 10 according to the present exemplary embodiment.

Power generation switch 10 according to the present exemplary embodiment generates electric power by operation of button unit 11 and wirelessly transmits a predetermined signal using the electric power thus generated. In other words, power generation switch 10 according to the present exemplary embodiment, which does not include a battery or the like, generates electric power every time power generation switch 10 is operated, to transmit the predetermined signal. Note that the operation of button unit 11 means, for example, pressing down button unit 11 by a user.

An example of the predetermined signal is a signal indicating unique identification information allocated to each power generation switch 10. Power generation switch 10 transmits the predetermined signal to a control device that controls various electrical devices installed in a house or the like. Various electrical devices include, for example, lighting devices, video display devices, and electric curtains For example, in the case where the identification information of power generation switch 10 and a process of turning on a lighting device are associated with each other in the control device, when the control device receives a signal from power generation switch 10, the control device performs the process of turning on the lighting device.

Power generation switch 10 according to the present exemplary embodiment can be carried by a user. For example, a user can place power generations switch 10 on a desk while the user is working on the desk or can place power generation switch 10 next to a bed while the user sleeps.

As illustrated in FIG. 1 and FIG. 2, power generation switch 10 includes button unit 11 and casing unit 12. Button unit 11 and casing unit 12 form the outline of power generation switch 10.

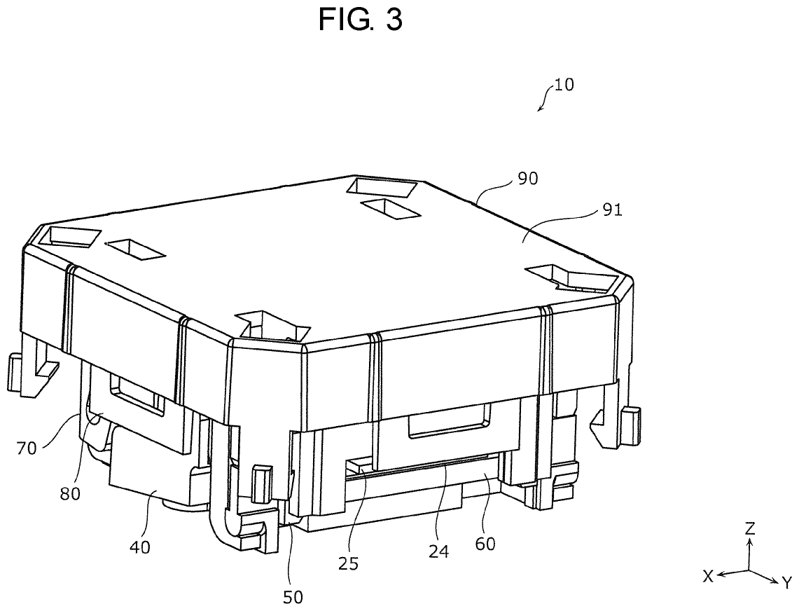

Next, structural elements housed in button unit 11 and casing unit 12 will be described with reference to FIG. 3 to FIG. 9.

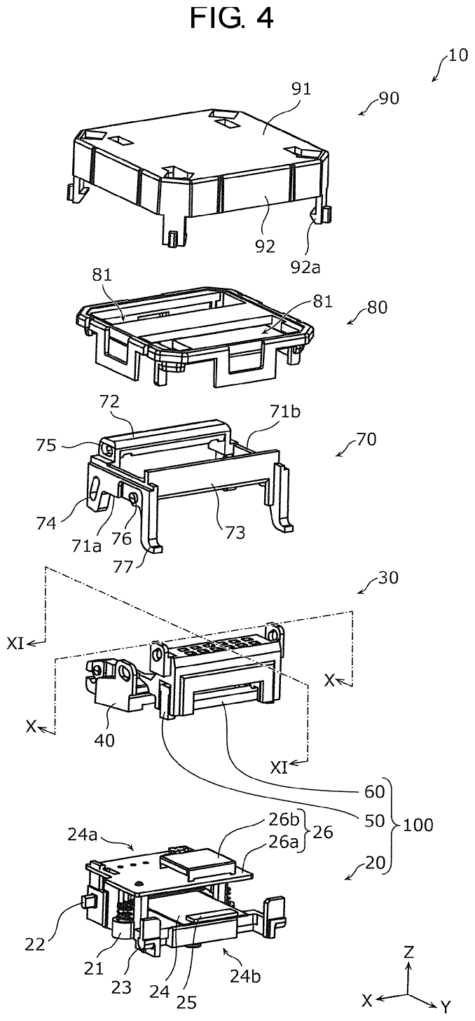

FIG. 3 is a perspective view illustrating the configuration of power generation switch 10 according to the present exemplary embodiment without button unit 11 and casing unit 12 in FIG. 1. FIG. 4 is an exploded perspective view illustrating the configuration of power generation switch 10 according to the present exemplary embodiment without button unit 11 and casing unit 12 in FIG. 1.

As illustrated in FIG. 3 and FIG. 4, power generation switch 10 according to the present exemplary embodiment with button unit 11 and casing unit 12 removed includes power generation device 100, arm unit 40, lever unit 70, cover unit 80, and lower button unit 90. Power generation device 100, which generates electric power through rotation of arm unit 40, includes power generation unit 20, magnet holding unit 50, and magnet 60. In the subsequent description, an assembly including magnet holding unit 50 and magnet 60, which are included in power generation device 100, attached to arm unit 40 will be referred to as vibration generation unit 30.

Hereinafter, the structural elements included in power generation switch 10 will be described with reference to the drawings, as appropriate. Note that the present disclosure is characterized by the configuration of vibration generation unit 30.

### [1-1. Button Unit and Casing Unit]

Button unit 11 and casing unit 12 will be described with reference to FIG. 1 and FIG. 2.

Button unit 11 and casing unit 12 are a housing that forms the outline of power generation switch 10. As illustrated in FIG. 1 and FIG. 2, each of button unit 11 and casing unit 12 has a bottom; button unit 11 includes upper surface portion 11a and side surface portion 11b vertically extending on the casing unit 12 side from the outer edge of upper surface portion 11a, and casing unit 12 includes bottom surface portion 12a and side surface portion 12b vertically extending on the button unit 11 side from the outer edge of bottom surface portion 12a. In a plan view, each of button unit 11 and casing unit 12 is formed into a substantially rectangular shape with four round corners. For example, each of button unit 11 and casing unit 12 is formed into a substantially square shape with four round corners in a plan view.

In the plan view, the size of button unit 11 is greater than the size of casing unit 12. Specifically, button unit 11 is disposed so that upper surface portion 11a is opposite to bottom surface portion 12a and side surface portion 11b of button unit 11 covers a part of side surface portion 12b of casing unit 12. Furthermore, power generation unit 20, vibration generation unit 30, lever unit 70, etc., to be described later are housed in the space formed by button unit 11 and casing unit 12.

Upper surface portion 11a is an operating surface which a user operates. Specifically, a user presses down upper surface portion 11a. This results in button unit 11 being pushed down toward a mounting surface on which power generation unit 10 is placed (in the present exemplary embodiment, from an area on the positive side of the Z-axis to an area on the negative side of the Z-axis).

Button unit 11 and casing unit 12 are formed of resin materials. For example, each of button unit 11 and casing unit 12 is formed of an acrylic resin, a polycarbonate resin, a polybutylene terephthalate (PBT) resin, polyoxymethylene (POM), an ABS resin (a copolymer of acrylonitrile, butadiene, and styrene), or the like. Note that the materials of button unit 11 and casing unit 12 are not limited to these materials. Button unit 11 and casing unit 12 may be formed of the same material or may include different materials. Button unit 11 and casing unit 12 may be formed of colored resin materials. With this, the structural elements housed in the space formed by button unit 11 and casing unit 12 are not viewable by users. Thus, the aesthetics of power generation switch 10 improve.

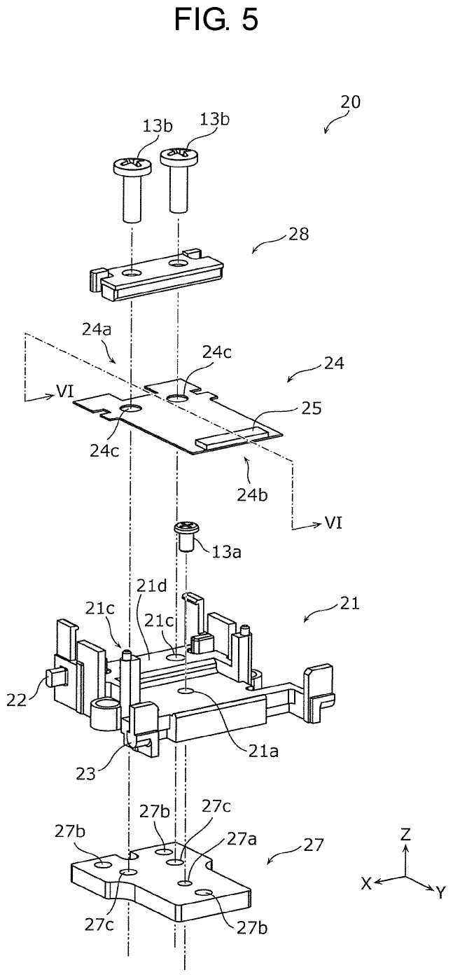

As illustrated in FIG. 2, bottom surface portion 12a of casing unit 12 has three openings, into each of which screw 13 is threaded. Casing unit 12 is joined to rigid plate 27 (refer to FIG. 5) of power generation unit 20 by threaded engagement using screws 13. Rigid plate 27 will be described later.

Note that top plate 91 of lower button unit 90 illustrated in FIG. 3 is fixed to upper surface portion 11a of button unit 11. For example, the surface of top plate 91 on the positive side of the Z-axis (the upper surface of top plate 91 in FIG. 3) and the surface of upper surface portion 11a of button unit 11 on the negative side of the Z-axis (the lower surface of upper surface portion 11a in FIG. 1) are bonded together using an adhesive tape or the like; thus, lower button unit 90 and button unit 11 are fixed. Note that fixing of lower button unit 90 and button unit 11 is not limited to fixing using the adhesive tape; it is sufficient that the fixing be performed in such a manner that button unit 11 does not separate from lower button unit 90. For example, lower button unit 90 and button unit 11 may be joined together by threaded engagement using screws or the like or other fixing methods may be used.

### [1-2. Power Generation Unit]

Next, power generation unit 20 will be described with reference to FIG. 3 to FIG. 6.

Power generation unit 20 is a device that generates electric power for transmitting the predetermined signal by operation of button unit 11 and transmits the predetermined signal. As illustrated in FIG. 3 and FIG. 4, with button unit 11 and casing unit 12 removed, power generation unit 20 is disposed below power generation unit 10 (in an area on the negative side of the Z-axis). Power generation unit 20 includes holding portion 21, power generation portion 24, signaling portion 26, and rigid plate 27.

First, holding portion 21, power generation portion 24, and rigid plate 27 which contribute to power generation will be described with reference to FIG. 5.

FIG. 5 is an exploded perspective view illustrating the configuration of power generation unit 20 according to the present exemplary embodiment. Note that illustration of signaling portion 26 is omitted in FIG. 5.

As illustrated in FIG. 5, power generation portion 24 is fixed to the surface of holding portion 21 on the positive side of the Z-axis, and rigid plate 27 is fixed to the surface of holding portion 21 on the negative side of the Z-axis. First, fixing of the structural elements will be described.

Power generation unit 20 includes a fixing member for fixing holding portion 21 to rigid plate 27. Power generation unit 20 includes a fixing member for fixing a part of power generation unit 24 on the fixing end 24a side to holding portion 21. In the present exemplary embodiment, power generation unit 20 includes screw 13a for joining holding portion 21 to rigid plate 27 by threaded engagement. Power generation unit 20 includes screw 13b for joining the part on the fixing end 24a side to holding portion 21. In the present exemplary embodiment, power generation unit 24, holding portion 21, and rigid plate 27 are integrally joined together by threaded engagement using screw 13b via screw holder portion 28. In other words, screw 13b is a fixing member shared to fix fixing end 24a, holding portion 21, and rigid plate 27. By screws 13a, 13b fixing power generation portion 24 and rigid plate 27 to holding portion 21, holding portion 21 holds power generation portion 24 and rigid plate 27.

Note that fixing of holding portion 21 and rigid plate 27 and fixing of power generation portion 24 and holding portion 21 are not limited to the threaded engagement. In other words, the fixing member is not limited to screws 13a, 13b. For example, holding portion 21 may be fixed to rigid plate 27 using an adhesive. Power generation portion 24 may be fixed to holding portion 21 using an adhesive. Other fixing methods may be used.

Hereinafter, the structural elements will be described with reference to FIG. 5.

Holding portion 21 is a member to which fixing end 24a and rigid plate 27 are fixed. Holding portion 21 includes holder portion 21d to which fixing end 24a is fixed. In holding portion 21, holder portion 21d is located in the negative direction of the Y-axis relative to magnet 60 when viewed in the X-axis direction. Furthermore, holding portion 21 has screw holes 21a, 21c. Screw hole 21a is an opening for fixing holding portion 21 to rigid plate 27, and screw hole 21c is an opening for fixing power generation portion 24 to holder portion 21d. Screw hole 21c is an opening formed in holder portion 21d. Furthermore, holding portion 21 includes first projection 22 and second projection 23 on a side surface (the surface located in an area on the X-axis). For example, first projection 22 and second projection 23 may be formed integrally with holding portion 21.

First projection 22, which serves as a rotating shaft for rotating arm unit 40 to be described later, is formed to protrude, along the X-axis, from the side surface of holding portion 21 on the holder portion 21d side (the side surface on the negative side of the Y-axis). First projection 22 includes: a projection protruding on the positive side of the X-axis from the end of holding portion 21 on the positive side of the X-axis; and a projection protruding on the negative side of the X-axis from the end of holding portion 21 on the negative side of the X-axis. When viewed in the X-axis direction, the contour of first projection 22 is substantially oval with the major axis extending in the Z-axis direction. Note that first projection 22 is an example of the second shaft portion on which arm unit 40 is pivoted.

Second projection 23, which serves as a rotating shaft for rotating lever unit 70 to be described later, is formed to protrude, along the X-axis, from the side surface of holding portion 21 on the side on which power generation portion 24 is not fixed (the side surface on the positive side of the Y-axis). Second projection 23 includes: a projection protruding on the positive side of the X-axis from the end of holding portion 21 on the positive side of the X-axis; and a projection protruding on the negative side of the X-axis from the end of holding portion 21 on the negative side of the X-axis. When viewed in the X-axis direction, the contour of second projection 23 is substantially semicircular with the arc on the negative side of the Z-axis.

Holding portion 21 includes a resin material. For example, holding portion 21 is formed of an acrylic resin, a polycarbonate resin, a PBT resin, an ABS resin, or the like.

Power generation portion 24 includes magnetic plate 25 and a piezoelectric element and generates a voltage by the piezoelectric effect through bending vibrations. Power generation portion 24 is formed flat and has two screw holes 24c at one end. Screw holes 24c are openings for fixing power generation portion 24 to holder portion 21d. For example, power generation portion 24 and holder portion 21d are joined together by threaded engagement using screws 13b. In other words, power generation portion 24 has a cantilever structure having one end (in the present exemplary embodiment, the end on the negative side of the Y-axis) fixed as fixed end portion 24a and the other end (in the present exemplary embodiment, the end on the positive side of the Y-axis) as free end portion 24b. Power generation portion 24 generates electric power by free vibrations of free end portion 24b. In other words, power generation portion 24 includes: fixed end portion 24a fixed to holder portion 21d; and free end portion 24b which freely vibrates, and generates electric power by free vibrations of free end portion 24b. Note that fixed end portion 24a is an example of the fixed portion which is fixed to holder portion 21d.

The shape of power generation portion 24 in a plan view is, for example, substantially rectangular.

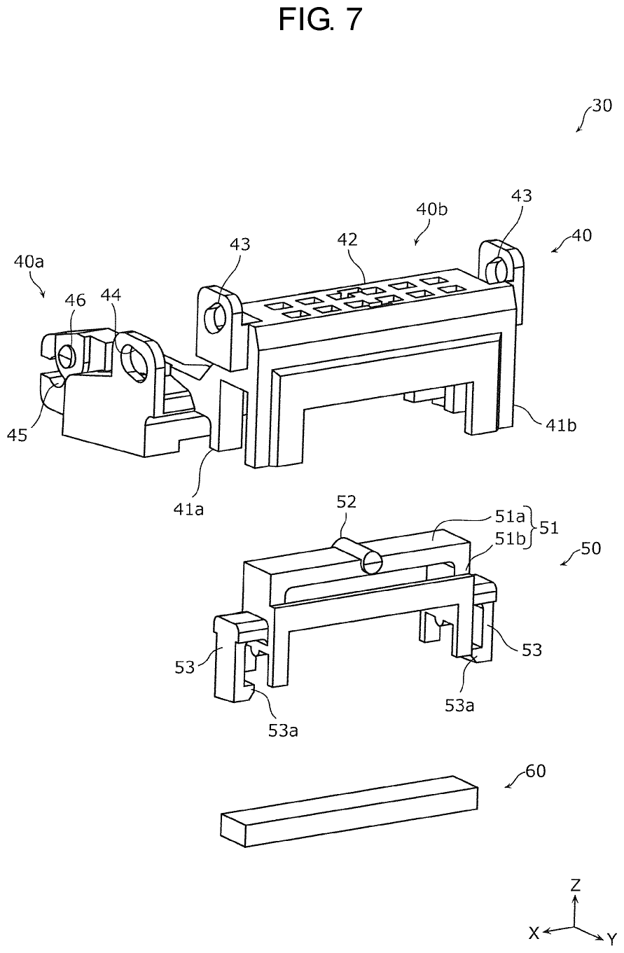

Magnetic plate 25 is formed of a magnetic material and is fixed to an end on the free end portion 24b side. Magnetic plate 25 is an example of an attracting element which attracts, by magnetic force, magnet 60 included in arm unit 40 (for example, refer to FIG. 7). Magnetic plate 25 may be fixed to a tip of power generation portion 24 near free end portion 24b. This allows magnetic plate 25 to concurrently function as a weight for power generation portion 24. Magnetic plate 25 extends in the width direction of power generation portion 24 (a direction parallel to the X-axis). Note that the width direction of power generation portion 24 is substantially orthogonal to a line connecting fixed end portion 24a and free end portion 24b of power generation portion 24 in a plan view and is an example of the second direction.

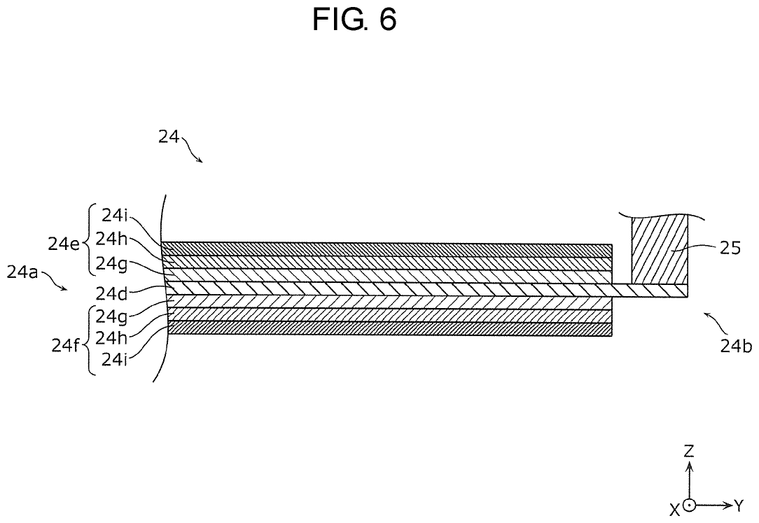

Here, the structure of power generation portion 24 will be described with reference to FIG. 6.

FIG. 6 is a partial cross-sectional view of power generation portion 24 according to the present exemplary embodiment, taken along line VI-VI in FIG. 5.

Power generation portion 24 includes: metal plate 24d which is thin; and a piezoelectric element disposed on at least one surface of metal plate 24d. As illustrated in FIG. 6, in the present exemplary embodiment, power generation portion 24 includes: metal plate 24d which is thin; and piezoelectric elements 24e, 24f which are thin plates disposed on both sides of metal plate 24d. Specifically, piezoelectric element 24e is disposed on the signaling portion 26 side (on the positive side of the Z-axis) of metal plate 24d, and piezoelectric element 24f is disposed on the holding portion 21 side (on the negative side of the Z-axis) of metal plate 24d. In other words, power generation portion 24 includes two piezoelectric elements 24e, 24f, and two piezoelectric elements 24e, 24f are disposed at opposite sides of metal plate 24d. For example, piezoelectric element 24e, metal plate 24d, and piezoelectric element 24f are stacked in this order in contact with each other. With this, greater electric power can be generated by free vibrations than in the case where there is a single piezoelectric element.

Metal plate 24d is formed of a spring material. For example, a metal material such as stainless steel can be used for metal plate 24d.

In piezoelectric element 24e, electrode 24g, piezoelectric body 24h, and electrode 24i are stacked in contact with each other in this order from metal plate 24d on the positive side of the Z-axis. In piezoelectric element 24f, electrode 24g, piezoelectric body 24h, and electrode 24i are stacked in contact with each other in this order from metal plate 24d on the negative side of the Z-axis. Electrodes 24g, 24i are for obtaining the voltage generated at piezoelectric body 24h. Note that electrodes 24g, 24i may be formed of metal materials or may be formed of oxide conductor materials.

Note that electrode 24g of piezoelectric element 24e and electrode 24g of piezoelectric element 24f have the same polarity. Electrode 24i of piezoelectric element 24e and electrode 24i of piezoelectric element 24f have the same polarity that is opposite that of electrode 24g. For example, when electrode 24i is positive, electrode 24g is negative, and when electrode 24i is negative, electrode 24g is positive. The electric power generated by power generation portion 24 is output to signaling portion 26 through a power line (not illustrated in the drawings).

Although not illustrated in the drawings, power generation portion 24 may include a rectifier, a voltage regulator, and the like. Alternating-current power generated by free vibrations of free end portion 24b is converted into direct-current power using, for example, a rectifier including a rectifier circuit and a capacitor, and then is stored. The voltage of the direct-current power is a few tens of volts, an example of which is approximately 50 V. Furthermore, the voltage regulator such as a DC-DC converter steps down the voltage so that no excessive voltage is applied to signaling portion 26. For example, the voltage regulator steps down the voltage to approximately 3 V, and this stepped-down electric power is used for signaling portion 26 to output signals.

In FIG. 6, the line connecting free end portion 24a and free end portion 24b of power generation portion 24 is parallel to the Y-axis and is an example of the third direction.

Referring back to FIG. 5, rigid plate 27 is a weight fixed to holding portion 21. Rigid plate 27 is, for example, a metal plate. Rigid plate 27 is disposed on the opposite side of holding portion 21 from power generation portion 24. Rigid plate 27 is formed of a non-magnetic material such as stainless steel, for example. The thickness of rigid plate 27 is not limited to a specific value; as an example, the thickness is approximately 2 mm. Note that rigid plate 27 may be formed of a magnetic material.

Upon free vibrations of power generation portion 24, the free vibrations may less easily attenuate. As a result of rigid plate 27 being fixed to holding portion 21, power generation unit 20 (power generation switch 10) becomes heavy, allowing the free vibrations of power generation portion 24 to last long. In other words, it is possible to reduce attenuation of the free vibrations of power generation portion 24; thus, the power generation efficiency of power generation unit 20 improves.

Furthermore, in the present exemplary embodiment, rigid plate 27 has: screw hole 27a for fixing rigid plate 27 to holding portion 21; screw hole 27b for fixing casing unit 12 to rigid plate 27; and screw hole 27c for fixing fixed end portion 24a of power generation portion 24, holder portion 21d, and rigid plate 27 using a shared fixing member. Note that the positions and the numbers of screw holes 27a-27c are not limited to the positions and the numbers illustrated in FIG. 5.

Referring back to FIG. 4, signaling portion 26 is a transmission device which when electric power is supplied from power generation portion 24, wirelessly transmits a predetermined signal using the electric power. In other words, signaling portion 26 operates only with the electric power supplied from power generation portion 24. Note that in one non-limiting example of the wireless communication, the ZigBee (registered trademark) communication standard is used; it is also possible to apply wireless communication in which a communication standard such as a wireless local area network (LAN) (for example, Wi-Fi (registered trademark)) is used.

As illustrated in FIG. 4, signaling portion 26 includes substrate 26a and shielding case 26b.

Substrate 26a is a board on which an electrical circuit including a transmission integrated circuit (IC) for transmitting a predetermined signal is mounted. For example, when supplied with electric power from power generation portion 24, the transmission IC performs control to generate a predetermined signal and transmit the predetermined signal through an antenna. Note that as mentioned above, the predetermined signal is, for example, information indicating identification information unique to each power generation switch 10. In other words, every time electric power is supplied from power generation unit 20, the transmission IC performs the control for transmitting the same signal. Furthermore, a wire-to-board connector or the like for receiving electric power supply from power generation portion 24 may be mounted on substrate 26a.

Shielding case 26b is formed of a metal material or the like and is fixed to substrate 26a. Shielding case 26b is connected to a ground potential point on an electrical circuit in order to protect the circuit from static electricity, external radio wave noise, and the like.

Furthermore, signaling portion 26 includes an antenna (not illustrated in the drawings) serving as a transmitter that transmits the signal generated at substrate 26a. The antenna is formed of a metal material, for example, and is electrically connected to the electrical circuit on substrate 26a.

Signaling portion 26 is held, for example, on holding portion 21.

### [1-3. Vibration Generation Unit]

With reference to FIG. 7 to FIG. 9 in addition to FIG. 3 and FIG. 4, vibration generation unit 30 will be described.

When button unit 11 is pressed down, rotation in vibration generation unit 30 causes power generation portion 24 to freely vibrate. As illustrated in FIG. 4, vibration generation unit 30 includes arm unit 40 and magnet holding unit 50. Furthermore, as illustrated in FIG. 3 and FIG. 4, arm unit 40 is covered by lower button unit 90. This makes it possible to cause arm unit 40 to be pushed down and rotate when lower button unit 90 is pushed down, that is, when button unit 11 is pressed down. When arm unit 40 rotates, power generation portion 24 attracting magnet 60 included in magnet holding unit 50 is bent, and magnet 60 and power generation portion 24 separate from each other, leading to free vibrations of power generation portion 24. Pressing down means that button unit 11 is pressed from a position on the positive side of the Z-axis down to a position on the negative side of the Z-axis.

FIG. 7 is an exploded perspective view illustrating the configuration of vibration generation unit 30 according to the present exemplary embodiment.

As illustrated in FIG. 7, in vibration generation unit 30, arm unit 40 which rotates when lower button unit 90 is pushed down and magnet holding unit 50 including magnet 60 are configured as separate elements. The present invention is characterized in that arm unit 40 and magnet holding unit 50 are separate elements and as will be described later, magnet holding unit 50 is rotatably held by arm unit 40.

Arm unit 40 includes arm 41a, arm 41b, and connecting portion 42. Furthermore, first opening 43 is formed in each of arms 41a, 41b on the positive side of the Y-axis (on the free end portion 24b side), second opening 44 is formed between the end on the free end portion 24b side and the end on the negative side of the Y-axis (on the fixed end portion 24a side), and third opening 45 is formed in each of arms 41a, 41b on the negative side of the Y-axis.

Arm 41a and arm 41b extend along the line connecting fixed end portion 24a and free end portion 24b of power generation portion 24 and are disposed substantially parallel to each other.

The end of each of arms 41a, 41b on the free end portion 24b side is fixed, for example, to lower button unit 90. Specifically, first opening 43 formed in each of arms 41a, 41b and a projection (not illustrated in the drawings) formed on the surface of lower button unit 90 on the negative side of the Z-axis fit together; thus, arm unit 40 and lower button unit 90 are joined together.

The end of each of arms 41a, 41b on the fixed end portion 24a side is rotatably attached to power generation unit 20. Specifically, the shape of third opening 45 formed in each of arms 41a, 41b corresponds to first projection 22, and arm unit 40 is pivoted on first projection 22 by first projection 22 fitting with third opening 45. Thus, arm unit 40 is attached to power generation unit 20 in such a manner as to be rotatable around first projection 22 as a rotation axis. For example, when viewed in the X-axis direction, the contour of each of third opening 45 and first projection 22 is substantially circular. Note that the end of each of arms 41a, 41b on the fixed end portion 24a side includes end portion 40a of arm unit 40 on the fixed end portion 24a side. In other words, end portion 40a, which is pivoted on first projection 22, is an example of the first end portion.

Furthermore, first projection 46 protruding outward from power generation switch 10 in a plan view is formed at the end of each of arms 41a, 41b on the fixed end portion 24a side. First projection 46 formed on each of arms 41a, 41b fits into first opening 74 (refer to FIG. 4) formed in lever unit 70 to be described later. Note that when first projection 46 is viewed along the pivot on first projection 22 (in the present exemplary embodiment, along the X-axis), the contour of first projection 46 is substantially circular.

As described above, arm unit 40 is attached to lower button unit 90 and power generation unit 20, and when button unit 11 is pressed down (for example, a section of button unit 11 that is located on the free end portion 24b side is pressed down) to cause lower button unit 90 to push down arm unit 40, arm unit 40 rotates around first projection 22 as a rotation axis. When pushed down by lower button unit 90, arm unit 40 rotates toward an area on the negative side of the Z-axis. In the present exemplary embodiment, when arm 41a is viewed from outside power generation switch 10 (in other words, when an area on the negative side of the X-axis is viewed from an area on the positive side of the X-axis), arm unit 40 rotates clockwise by being pushed down by lower button unit 90. Note that arms 41a, 41b are an example of one pair of arms included in arm unit 40.

Projection 76 (refer to FIG. 4) of lever unit 70 to be described later fits into second opening 44.

Connecting portion 42 connects ends of arms 41a, 41b that are located on the free end portion 24b side. As illustrated in FIG. 4, connecting portion 42 is formed extending along the X-axis. For example, when a point in button unit 11 that corresponds to the middle of connecting portion 42 in the X-axis direction is pressed down, arms 41a, 41b can rotate along with rotation of connecting portion 42. Note that the ends of arms 41a, 41b on the free end portion 24b side and connecting portion 42 are included in end portion 40b of arm unit 40 on the free end portion 24b side. End portion 40b is an example of the second end portion which moves in the Z-axis direction by rotation.

Arm unit 40 which rotates when button unit 11 is pressed down is an example of the moving unit. In the present exemplary embodiment, upon pressing down button unit 11, when an area on the negative side of the X-axis is viewed from an area on the positive side of the X-axis, arm unit 40 rotates around first projection 22 as a rotation axis toward an area on the Z-axis direction in which button unit 11 is pressed down. The rotation toward the area on the Z-axis direction means that when arm unit 40 is viewed from an area on the positive side of the X-axis to an area on the negative side of the X-axis, a direction parallel to the orientation of the speed of rotation (circular motion) of arm unit 40 includes a direction parallel to the direction in which button unit 11 is pressed down. In other words, although the orientation of the speed of arm unit 40 changes with time while arm unit 40 rotates, it is sufficient that a direction parallel to the Z-axis be included in a direction parallel to the orientation of the speed of arm unit 40. In this case, the direction parallel to the Z-axis is an example of the first direction. For example, the first direction, the second direction, and the third direction are orthogonal to one another.

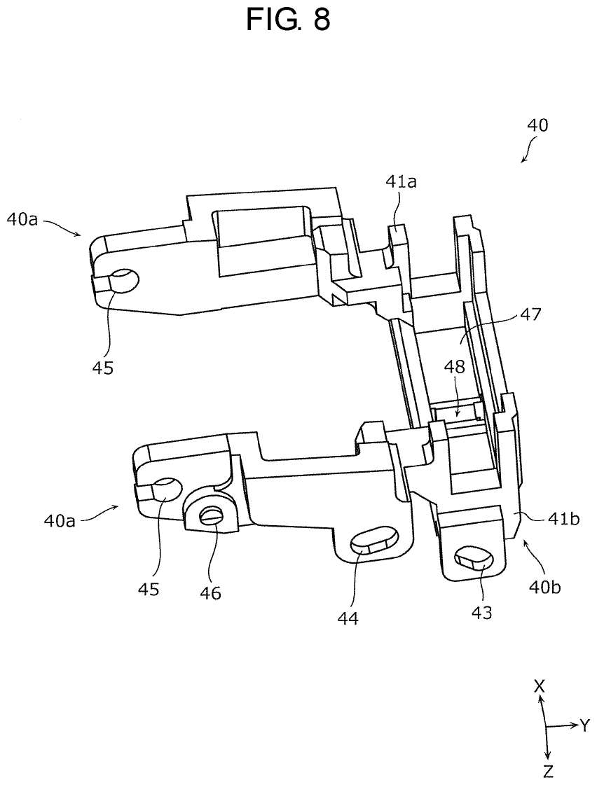

Furthermore, arm unit 40 includes an insertion portion into which rotating shaft portion 52 formed on magnet holding unit 50 to be described later is inserted. The insertion portion of arm unit 40 will be described with reference to FIG. 8.

FIG. 8 is a perspective view illustrating the configuration of arm unit 40 according to the present exemplary embodiment. Specifically, FIG. 8 is a perspective view of arm unit 40 when viewed from the negative side of the Z-axis.

As illustrated in FIG. 8, main surface portion 47 of arm unit 40 has insertion portion 48 into which rotating shaft portion 52 of magnet holding unit 50 is inserted. As with connecting portion 42, main surface portion 47 is formed extending in the width direction of power generation portion 24. In the present exemplary embodiment, insertion portion 48 includes a recess into which rotating shaft portion 52 of magnet holding unit 50 is inserted. The shape of insertion portion 48 is determined, as appropriate, according to the shape of rotating shaft portion 52; insertion portion 48 is, for example, a recess in the shape of a semicircular column (in other words, in the shape of a half barrel). Furthermore, the position of insertion portion 48 is determined, as appropriate, according to the position of rotating shaft portion 52; insertion portion 48 is disposed, for example, in an area located substantially in the middle of main surface portion 47 in the X-axis direction. Main surface portion 47, which is a section of connecting portion 42 that is located on the magnet holding unit 50 side, is an example of the first main surface portion.

Referring back to FIG. 7, magnet holding unit 50 will be described next.

As illustrated in FIG. 7, magnet holding unit 50 includes body portion 51, rotating shaft portion 52, and holding portion 53. Furthermore, magnet holding unit 50 includes magnet 60. Note that magnet holding unit 50 is an example of the attracting unit including magnet 60.

Body portion 51 includes: main surface portion 51a disposed facing main surface portion 47 of arm unit 40; and standing portions 51b vertically extending on the power generation unit 20 side (i.e., on the negative side of the Z-axis) from both ends of main surface portion 51a.

Main surface portion 51a is a substantially rectangular rod member formed extending in the width direction of power generation portion 24. In the present exemplary embodiment, rotating shaft portion 52 protruding from main surface portion 51a toward main surface portion 47 is disposed in an area located substantially in the middle of main surface portion 51a in the X-axis direction. When viewed in the Y-axis direction, the contour of rotating shaft portion 52 is substantially circular. For example, rotating shaft portion 52 is in the shape of a circle having a diameter of 5 mm. Specifically, when viewed in the Y-axis direction, a part of the arc of rotating shaft portion 52 protrudes from a surface of main surface portion 51a (that is, the surface on the positive side of the Z-axis) toward main surface portion 47, thus forming rotating shaft portion 52. This protruding section is inserted into insertion portion 48, and thus arm unit 40 and magnet holding unit 50 fit together. Note that main surface portion 51a is an example of the second main surface portion. Rotating shaft portion 52 is an example of the first shaft portion which includes at least a part protruding from main surface portion 51a toward main surface portion 47. Note that the first shaft portion may protrude from the first main surface portion toward the second main surface portion.

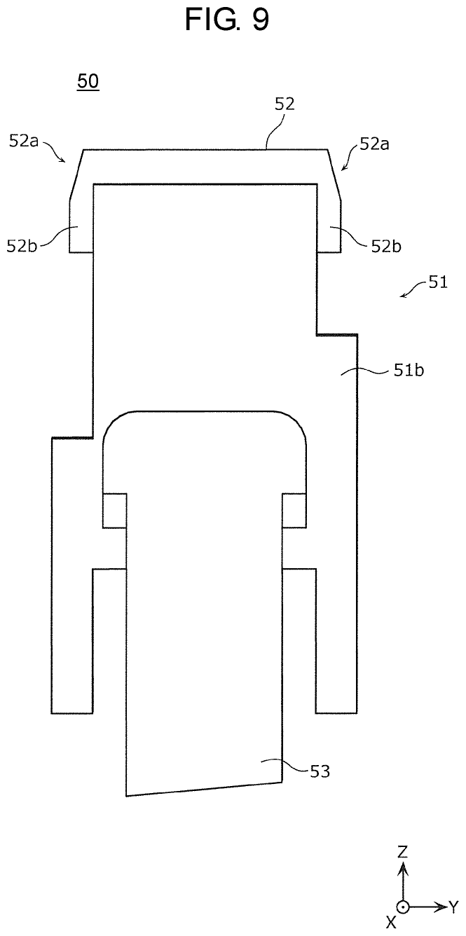

Next, the shape of rotating shaft portion 52 will be described in detail with reference to FIG. 9.

FIG. 9 is a diagram illustrating the configuration of magnet holding unit 50 according to the present exemplary embodiment. Specifically, FIG. 9 is a diagram of magnet holding unit 50 viewed from the positive side of the X-axis.

As illustrated in FIG. 9, rotating shaft portion 52 is formed extending in the Y-axis direction (i.e., along the line connecting fixed end portion 24a and free end portion 24b) and having a length greater than the length of main surface portion 51 in the Y-axis direction. Specifically, rotating shaft portion 52 includes projection 52b protruding from main surface portion 51a in the Y-axis direction. With this, after insertion of rotating shaft portion 52 into insertion portion 48, movement of rotating shaft portion 52 can be restricted.

As illustrated in FIG. 7 and FIG. 9, the shape of rotating shaft portion 52 is in the shape of a substantially circular column extending in the Y-axis direction. Furthermore, as illustrated in FIG. 9, the end of rotating shaft portion 52 on the arm unit 40 side (that is, on the insertion portion 48 side) includes cutout portion 52a obtained by cutting off a part of rotating shaft portion 52. This facilitates insertion of rotating shaft portion 52 into insertion portion 48. The workability for inserting rotating shaft portion 52 into insertion portion 48 improves.

Referring back to FIG. 7, standing portions 51b are formed extending substantially perpendicularly from the both ends of main surface portion 51a. Furthermore, holding portions 53 including claw portions 53a for fixing magnet 60 are formed on side surfaces of standing portions 51b. Holding portions 53 fix magnet 60 at a predetermined distance from main surface portion 51a. This makes it possible to dispose power generation portion 24 between main surface portion 51a and magnet 60. Furthermore, it is possible to reduce contact between power generation portion 24 and magnet holding unit 50 upon free vibrations of power generation portion 24.

Magnet 60 is a member for causing free vibrations of power generation portion 24 by moving in the Z-axis direction together with arm unit 40 to be placed in the state of magnetic attraction to free end portion 24b and the state of release from the state of magnetic attraction.

Magnet 60 is formed extending in the width direction of power generation portion 24 when viewed in the Z-axis direction. This allows magnet 60 to come into surface contact with free end portion 24b and thus attract free end portion 24b by a stronger force. In other words, the free vibrations of free end portion 24b (specifically, the amplitude of free vibrations) can be made larger, allowing an increase in electric power that is generated at power generation portion 24.

Magnet 60 is disposed at a position overlapping magnetic plate 25 disposed at an end of power generation portion 24 on the free end portion 24b side in a plan view. For example, magnet 60 is disposed in contact with the end of power generation portion 24 on the free end portion 24b side in the state where power generation portion 24 is not bent. Note that the state where power generation portion 24 is not bent is the state where a user is not operating button unit 11 and will also be referred to as a default state. In other words, in the default state, magnet 60 is magnetically attracted to magnetic plate 25 (refer to FIG. 3).

Arm unit 40 and magnet holding unit 50 include resin materials. For example, each of arm unit 40 and magnet holding unit 50 is formed of an acrylic resin, a polycarbonate resin, a PBT resin, an ABS resin, or the like. For example, the structural elements included in arm unit 40 may be integrally formed. Furthermore, the structural elements included in magnet holding unit 50 may be integrally formed. Moreover, for example, arm unit 40 and magnet holding unit 50 may be formed of the same material.

Note that although the foregoing describes an example where insertion portion 48 is formed in arm unit 40 and rotating shaft portion 52 is formed in magnet holding unit 50, this is not limiting. It is sufficient that rotating shaft portion 52 be formed in at least one of arm unit 40 and magnet holding unit 50 and insertion portion 48 into which rotating shaft portion 52 is to be inserted be formed in the other. For example, rotating shaft portion 52 may be formed in arm unit 40, and insertion portion 48 may be formed in magnet holding portion 50. In this case, at least a part of arm unit 40 may include rotating shaft portion 52 which protrudes from main surface portion 47 toward main surface portion 51a and extends in the Y-axis direction (in other words, along the line connecting fixed end portion 24a and free end portion 24b), and magnet holding unit 50 may include insertion portion 48 into which rotating shaft portion 52 is inserted.

### [1-4. Lever Unit]

Referring back to FIG. 3 and FIG. 4, lever unit 70 will be described next.

As illustrated in FIG. 3, lever unit 70 is covered by lower button unit 90. This makes it possible to cause lever unit 70 to be pushed down and rotate when lower button unit 90 is pushed down.

As illustrated in FIG. 4, lever unit 70 includes arm 71a, arm 71b, first connecting portion 72, and second connecting portion 73. Furthermore, first opening 74 is formed in an area of each of arms 71a, 71b on the fixed end portion 24a side, and second openings 75 are formed at both ends of first connecting portion 72. Second opening 75 is formed at a position closer to lower button unit 90 than first opening 74 is.

An end of lever unit 70 on the fixed end portion 24a side is fixed to lower button unit 90. Specifically, second opening 75 formed at first connecting portion 72 fits with a projection (not illustrated in the drawings) formed on a surface of lower button unit 90 on the negative side of the Z-axis; thus, lever unit 70 and lower button unit 90 are joined together. Note that first projection 46 formed in arm unit 40 fits into first opening 74.

Arm 71a and arm 71b extend along the line connecting fixed end portion 24a and free end portion 24b of power generation portion 24 and are disposed substantially parallel to each other. Projections 76 protruding outward from power generation switch 10 in a plan view are formed on arms 71a, 71b. Projections 76 formed on arms 71a, 71b fit with second openings 44 formed in arms 41a, 41b. Thus, lever unit 70 and arm unit 40 are joined together. Note that when projection 76 is viewed in the width direction of power generation portion 24, the contour of projection 76 is substantially circular.

The end of each of arms 71a, 71b on the free end portion 24b side is rotatably attached to power generation unit 20. Specifically, at the end of each of arms 71a, 71b on the free end portion 24b side, curved portion 77 having a curved shape corresponding to the substantially semicircular shape of second projection 23 of power generation unit 20 when viewed in the X-axis direction is formed. Curved portion 77 is disposed so as to abut second projection 23. Note that arms 71a, 71b are an example of one pair of arms included in arm unit 70.

First connecting portion 72 connects the ends of arms 71a, 71b on the fixed end portion 24a side. First connecting portion 72 is formed extending parallel to the width direction of power generation portion 24. For example, when a point in button unit 11 that corresponds to the middle of first connecting portion 72 in the X-axis direction is pressed down, arms 71a, 71b can rotate along with rotation of first connecting portion 72.

Second connecting portion 73 connects the ends of arms 71a, 71b on the free end portion 24b side. Second connecting portion 73 is formed extending parallel to the width direction of power generation portion 24.

As described above, lever unit 70 is attached to lower button unit 90 and power generation unit 20, and when button unit 11 is pressed down (for example, a section of button unit 11 that is located on the fixed end portion 24a side is pressed down) to cause lower button unit 90 to push down lever unit 70, lever unit 70 rotates around second projection 23 as a rotation axis. When pushed down by lower button unit 90, lever unit 70 rotates toward an area on the negative side of the Z-axis. In the present exemplary embodiment, when arm 71a is viewed from outside power generation switch 10 (in other words, when an area on the negative side of the X-axis is viewed from an area on the positive side of the X-axis), lever unit 70 rotates counterclockwise by being pushed down by lower button unit 90. This means that when lever unit 70 is pushed down by lower button unit 90, lever unit 70 rotates opposite to arm unit 40.

Furthermore, lever unit 70 has a structure capable of rotating to rotate arm unit 40. As an example, arms 71a, 71b may include projections (not illustrated in the drawings) protruding toward arms 41a, 41b (in other words, on the negative side of the Z-axis). For example, arms 71a, 71b include, at positions located substantially in the middle of respective arms 71a, 71b in the Y-axis direction, projections protruding toward arms 41a, 41b. For example, the projections of arms 71a, 71b are positioned to partially overlap arms 41a, 41b in a plan view. As a result, when a section of button unit 11 on the negative side of the Y-axis is pressed down and lever unit 70 rotates, the projections formed on arms 71a, 71b can push down arms 41a, 41b of arm unit 40. Thus, even when a point in button unit 11 on the fixed end portion 24a side is pressed down, lever unit 70 causes arm unit 40 to rotate, making it possible to generate electric power at power generation unit 20. This means that the operability of power generation switch 10 improves. Note that the projections formed on arms 71a, 71b and arms 41a, 41b may be in abutment in the state where button unit 11 is not pressed down.

Lever unit 70 includes a resin material. For example, lever unit 70 is formed of an acrylic resin, a polycarbonate resin, a PBT resin, an ABS resin, or the like. For example, the structural elements included in lever unit 70 may be integrally formed.

As described above, power generation switch 10 includes: arm unit 40 having a pivoted end on the fixed end portion 24a side; and lever unit 70 having a pivoted end on the free end portion 24b side. Rotation of lever unit 70 causes arm unit 40 to be pushed down and rotate. Note that lever unit 70 is not an essential structural element of power generation switch 10.

### [1-5. Cover Unit]

Next, cover unit 80 will be described with reference to FIG. 4.

As illustrated in FIG. 4, cover unit 80 is disposed so as to cover vibration generation unit 30 and lever unit 70. Cover unit 80 is a member that covers, from the button unit 11 side, a connected element obtained by fittingly connecting power generation unit 20, vibration generation unit 30, and lever unit 70, when the connected element is housed in casing unit 12. When side surface portion 12b of casing unit 12 and a side surface portion of cover unit 80 fit together, cover unit 80 is fixed to casing unit 12.

Furthermore, cover unit 80 has opening 81 at a position corresponding to each of connecting portion 42 of arm unit 40 and first connecting portion 72 of lever unit 70. This makes it possible to connect arm unit 40 and lower button unit 90 and connect lever unit 70 and lower button unit 90.

Cover unit 80 includes a resin material. For example, cover unit 80 is formed of an acrylic resin, a polycarbonate resin, a PBT resin, an ABS resin, or the like.

### [1-6. Lower Button Unit]

Next, lower button unit 90 will be described with reference to FIG. 3 and FIG. 4.

As illustrated in FIG. 3, lower button unit 90 is disposed so as to cover arm unit 40 and lever unit 70.

As illustrated in FIG. 4, lower button unit 90 includes top plate 91 and side surface portion 92. Lower button unit 90 has a substantially rectangular shape with cut corners in a plan view.

Top plate 91 is disposed substantially parallel to upper surface portion 11a of button unit 11. For example, top plate 91 and upper surface portion 11a are bonded together using an adhesive tape or the like; thus, lower button unit 90 and button unit 11 are fixed. In other words, when a user presses down button unit 11 (specifically, upper surface portion 11a of button unit 11), lower button unit 90 is pushed down together with button unit 11.

Side surface portion 92 is formed vertically extending from an end of top plate 91 on the power generation unit 20 side. Claw portions 92a protruding on the power generation unit 20 side are formed at the four corners of side surface portion 82. Claw portions 92a are projections for joining casing unit 12 and lower button unit 90 together. Recesses (not illustrated in the drawings) are formed at positions on the side surface portion of casing unit 12 that correspond to claw portions 92a, and claw portions 92a are hooked in the recesses to prevent lower button unit 90 from being detached from casing unit 12. Furthermore, the recesses are formed so that lower button unit 90 can be pushed down and move in the negative direction of the Z-axis.

Lower button unit 90 includes a resin material. For example, lower button unit 90 is formed of an acrylic resin, a polycarbonate resin, a PBT resin, an ABS resin, or the like. For example, the structural elements included in lower button unit 90 may be integrally formed.

[2. Connection between Arm Unit and Magnet Holding Unit]

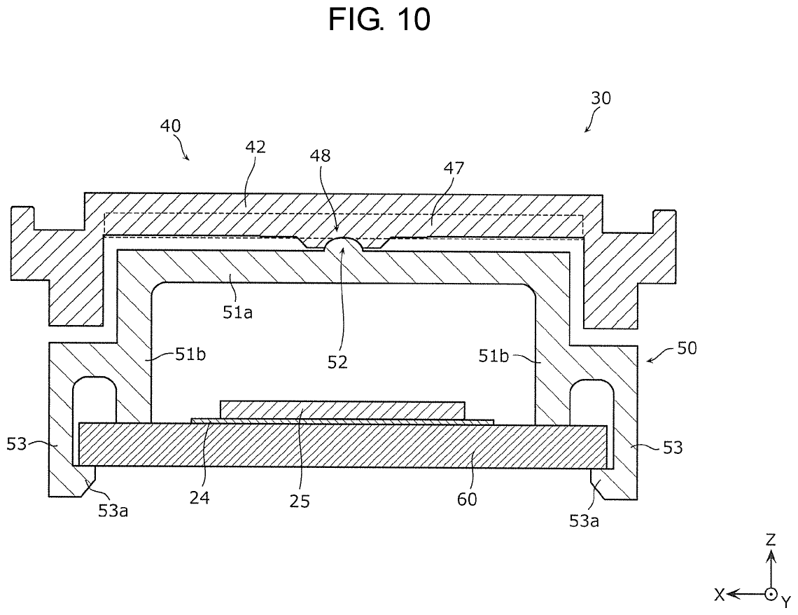

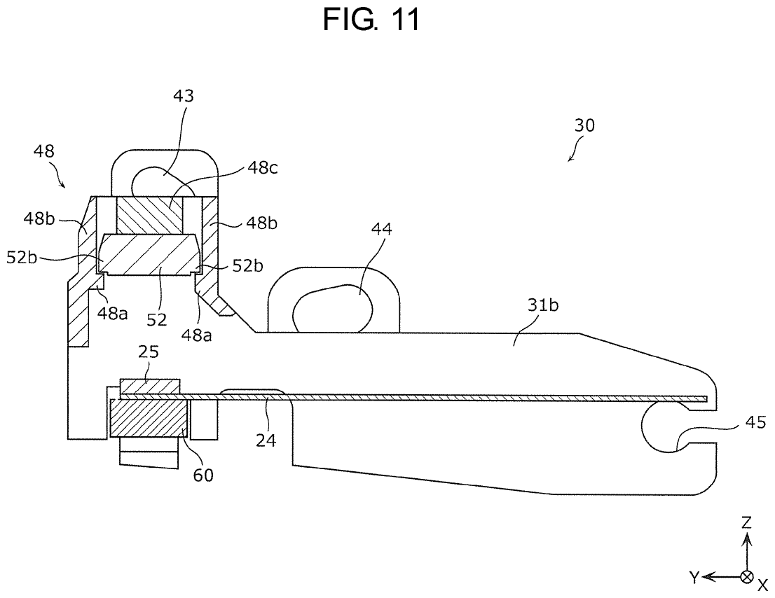

Next, the connection between arm unit 40 and magnet holding unit 50 will be described with reference to FIG. 10 and FIG. 11.

FIG. 10 is a partial cross-sectional view of vibration generation unit 30 according to the present exemplary embodiment, taken along line X-X in FIG. 4. Note that in FIG. 10, only a cross-section is illustrated. FIG. 11 is a partial cross-sectional view of vibration generation unit 30 according to the present exemplary embodiment, taken along line XI-XI in FIG. 4. Note that in FIG. 10 and FIG. 11, power generation unit 24 and magnetic plate 25 are illustrated as well. In FIG. 10 and FIG. 11, cross-sections in the default state are illustrated.

As illustrated in FIG. 10, a portion projecting from main surface portion 51a of rotating shaft portion 52 toward the main surface portion 47 of arm unit 40 is inserted into insertion portion 48 of arm unit 40. In this state, magnet holding unit 50 is held only through interfitting of insertion portion 48 and rotating shaft portion 52. This means that magnet holding unit 50 is not connected to holding portion 21, lever unit 70, or the like.

The direction of the rotation axis of magnet holding unit 50 is the direction in which rotating shaft portion 52 extends and is the Y-axis direction. In other words, the rotation axis of magnet holding unit 50 extends along the line connecting fixed end portion 24a and free end portion 24b. Magnet holding unit 50 rotates around rotating shaft portion 52.

Although FIG. 10 illustrates an example in which rotating shaft portion 52 and insertion portion 48 are at least partially in contact with each other, rotating shaft portion 52 and insertion portion 48 are not required to be in contact with each other in the default state.

As illustrated in FIG. 11, insertion portion 48 is configured to accommodate rotating shaft portion 52. Specifically, in a cross-sectional view, insertion portion 48 accommodates rotating shaft portion 52 by claw portion 48a, side wall portion 48b, and upper wall portion 48c. Claw portion 48a is formed protruding from a part of side wall portion 48b into insertion portion 48 and supports the bottom (that is, a portion on the negative side of the Z-axis) of projection 52b of rotating shaft portion 52. For example, claw portion 48a is in linear contact with the bottom of projection 52b.

Side wall portions 48b are disposed at opposite sides of rotating shaft portion 52 in the Y-axis direction and restricts movement of rotating shaft portion 52 in the Y-axis direction. For example, side wall portions 48b may be disposed at least partially in contact with side portions (in other words, portions on the positive and negative sides of the Y-axis) of projection 52b of rotating shaft portion 52.

As illustrated in FIG. 10 and FIG. 11, upper wall portion 48c is formed to at least partially cover rotating shaft portion 52. For example, upper wall portion 48c is formed having a curvature in a cross-section taken along the XZ plane, as illustrated in FIG. 10. This allows upper wall portion 48c to regulate movements of rotating shaft portion 52 in the positive direction of the Z-axis and in the X-axis direction.

Note that the shape of insertion portion 48 is not limited to the shape described above; it is sufficient that insertion portion 48 have such a shape as to keep rotating shaft portion 52 from moving in the X-axis direction. Insertion portion 48 may be a through-hole corresponding to the shape of rotating shaft portion 52. In other words, side wall portion 48b is not required.

As illustrated in FIG. 10 and FIG. 11, in the state where magnet 60 is held by magnet holding unit 50 and magnet holding unit 50 is attached to arm unit 40, magnet 60 is in contact with power generation portion 24. Specifically, magnet 60 and free end portion 24b are in surface contact with each other. As a result, the magnetic attraction between magnet 60 and power generation unit 24 increases, making it possible to increase electric power that is generated upon free variations of free end portion 24b.

### [3. Operation of Power Generation Switch]

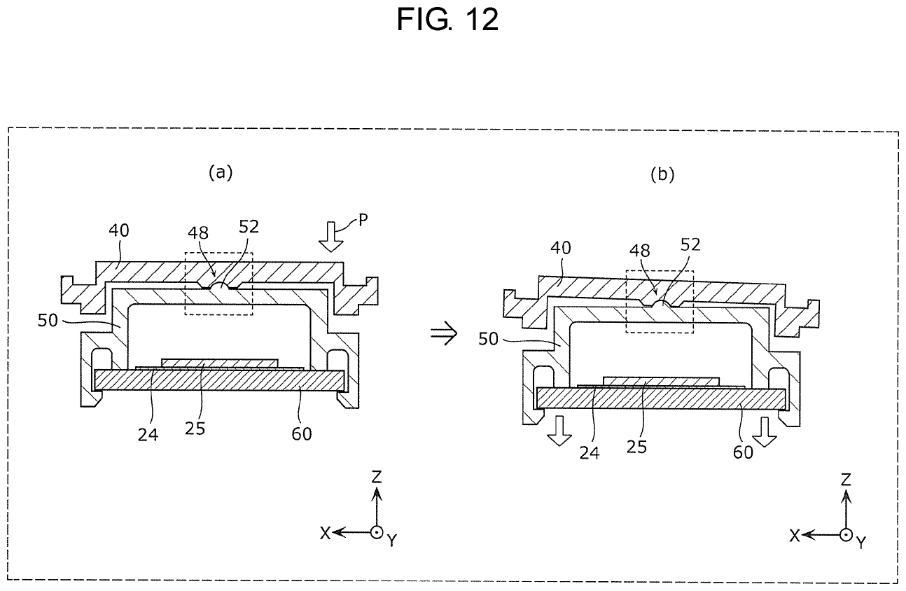

Next, the state of power generation switch 10 when button unit 11 of power generation switch 10 is pressed down, which is described above, will be described with reference to FIG. 12.

FIG. 12 is a schematic diagram illustrating movement of vibration generation unit 30 before and after operation of button unit 11 according to the present exemplary embodiment. Specifically, FIG. 12 is a partial cross-sectional view of vibration generation unit 30 according to the present exemplary embodiment, taken along line X-X in FIG. 4. In (a) in FIG. 12, the state of vibration generation unit 30 before button unit 11 is pressed down is illustrated. Note that in FIG. 12, power generation unit 24 and magnetic plate 25 are illustrated as well.

As illustrated in (a) in FIG. 12, magnet 60 and power generation portion 24 (specifically, free end portion 24b (refer to FIG. 5)) are in contact with each other before button unit 11 is pressed down. Note that at this point in time, arm unit 40 is not rotating around rotating shaft portion 52 as a rotation axis. With reference to (b) in FIG. 12, the state of vibration generation unit 30 when a point in button unit 11 that corresponds to the position indicated by arrow P in the figure is pressed down will be described. In (b) in FIG. 12, the state of vibration generation unit 30 after button unit 11 is pressed down is illustrated. Note that the position in button unit 11 that corresponds to the position indicated by arrow P represents a position on upper surface portion 11a of button unit 11 in FIG. 1, in a region on the positive side of the Y-axis and on the negative side of the X-axis.

As illustrated in (b) in FIG. 12, when the position indicated by arrow P in (a) in FIG. 12 is pressed down, arm unit 40 is tilted according to the pressed position. Here, tilting of arm unit 40 means rotation (in other words, twisting) of arm unit 40 around the Y-axis as a rotating axis from the default state when arm unit 40 is viewed in the Y-axis direction. Thus, pushing down of connecting portion 42 while remaining parallel to the Y-axis direction when button unit 11 is pressed down means that no tilting has occurred. The state where no tilting has occurred will be referred to also as a parallel state.

In the present exemplary embodiment, since magnet holding unit 50 is structurally separate from arm unit 40 and is rotatably held by arm unit 40, even when arm unit 40 is tilted, magnet holding unit 50 is not tilted along with arm unit 40. This is because, since magnet holding unit 50 rotates with respect to arm unit 40 via rotating shaft portion 52, effects of the tilting of arm unit 40 less easily propagate to magnet holding unit 50. In other words, even when arm unit 40 is tilted, magnet holding unit 50 can remain in the default state without following the tilting. Furthermore, in the state of being pressed, rotating shaft portion 52 and insertion portion 48 are in contact with each other, and rotating shaft portion 52 can rotate by insertion portion 48 toward an area on the negative side of the Z-axis (refer to the arrow in (b) in FIG. 12) while remaining in the parallel state. Thus, magnet holding unit 50 allows power generation portion 24 to be bent while magnet 60 and power generation portion 24 remain in surface contact with each other.

For example, if the vibration generation unit does not include the rotating shaft portion and the arm unit and the magnet holding unit are fixed, when the position in the button unit that corresponds to the position indicated by arrow P in (a) in FIG. 12 is pressed down, the arm unit and the magnet holding unit are tilted in the same manner. When the magnet holding unit is tilted, the magnet is also tilted. Therefore, it would be difficult to cause the power generation unit to be bent in the state where the magnet and the power generation portion are in surface contact with each other as illustrated in (b) in FIG. 12. In other words, generated electric power varies depending on the pressing position in the power generation switch.

As described above, in power generation switch 10 according to the present exemplary embodiment, arm unit 40 which rotates when button unit 11 is pressed down and magnet holding unit 50 which fixes magnet 60 are formed as separate elements, and arm unit 40 and magnet holding unit 50 are rotatably joined together. Note that the rotation axis around which magnet holding unit 50 rotates is substantially parallel to the line connecting fixed end portion 24a and free end portion 24b of power generation portion 24.

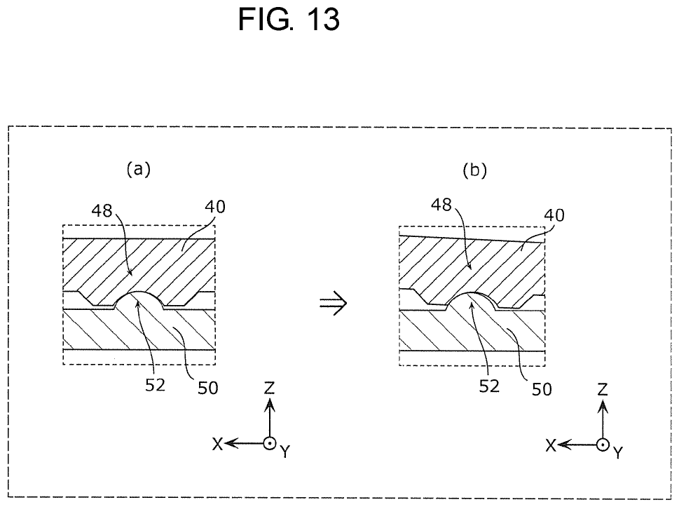

Insertion portion 48 may be formed to allow movement of rotating shaft portion 52 in the Z-axis direction. For example, insertion portion 48 may be formed having a smaller curvature than the curvature of rotating shaft portion 52. Operations of power generation switch 10 having such a configuration will be described with reference to FIG. 13.

FIG. 13 is a schematic diagram illustrating another example of the state of vibration generation unit 30 before and after operation of button unit 11 according to the present exemplary embodiment.

In (a) in FIG. 13, the state of vibration generation unit 30 before button unit 11 is pressed down is illustrated. In (b) in FIG. 13, the state of vibration generation unit 30 after button unit 11 is pressed down is illustrated. Note that (a) in FIG. 13 is an expanded view of a region corresponding to the region enclosed by the dashed line in (a) in FIG. 12, and (b) in FIG. 13 is an expanded view of a region corresponding to the region enclosed by the dashed line in (b) in FIG. 12.

As illustrated in (a) and (b) in FIG. 13, insertion portion 48 is formed having a smaller curvature of the curvature of rotating shaft portion 52, allowing a reduction in the area of contact between insertion portion 48 and rotating shaft portion 52; thus, it is possible to reduce the resistance force due to friction that is applied to rotating shaft portion 52 upon rotation of magnet holding unit 50 relative to arm unit 40. Accordingly, it is possible to reduce stress that is applied to rotating shaft portion 52, leading to a reduction in damage to rotating shaft portion 52. Furthermore, since the resistance force due to friction can be reduced, rotating shaft portion 52 can smoothly rotate relative to insertion portion 48. Thus, it is possible to further keep magnet holding unit 50 from following the tilting of arm unit 40.

### [4. Effects]

As described above, power generation switch 10 according to the present exemplary embodiment includes: arm unit 40 including at least a part that rotates toward an area in the Z-axis direction; and power generation device 100 which generates electric power through rotation of arm unit 40. Power generation device 100 includes: magnet holding unit 50 which moves in the Z-axis direction through rotation of arm unit 40 which moves in the Z-axis direction through the rotation of arm unit 40 and includes magnet 60 extending in the X-axis direction; holder portion 21d located in the negative direction of the Y-axis relative to magnet 60; and plate-shaped power generation portion 24 which includes (i) free end portion 24b that is placed in the state of attraction to magnet 60 and the state of release from the state of attraction and (ii) fixed end portion 24a that is fixed to holder portion 21d, and generates electric power by free vibrations of free end portion 24b. Magnet holding unit 50 is rotatably held by arm unit 40.

Thus, when power generation switch 10 is pressed down, arm unit 40 rotates toward an area in the Z-axis direction. For example, when pressure applied to arm unit 40 is out of balance, arm unit 40 is tilted and in this state rotates toward the area in the Z-axis direction. Meanwhile, since magnet holding unit 50 is held in such a manner as to be rotatable around arm unit 40, the tilt of magnet holding unit 50 that occurs due to the tilt of arm unit 40 can be reduced. Specifically, even when arm unit 40 is tilted, magnet holding unit 50 can maintain the parallel state of magnet 60, and thus, there can be attraction (i.e., the area of contact) between power generation portion 24 and magnet 60. This enables power generation switch 10 to stably generate electric power, resulting in improved operability.

Furthermore, the rotation axis of magnet holding unit 50 is parallel to the line connecting fixed end portion 24a and free end portion 24b.

With this, when arm unit 40 is tilted, magnet holding unit 50 can rotate around a line parallel to the line connecting fixed end portion 24a and free end portion 24b as the rotation axis, with respect to arm unit 40. In other words, magnet holding unit 50 can reduce tilting of power generation portion 24 around the direction parallel to the line connecting fixed end portion 24a and free end portion 24b as an axis. This further enables power generation switch 10 to stably generate electric power.

Furthermore, arm unit 40 includes main surface portion 47 extending in the width direction of power generation portion 24, and magnet holding unit 50 includes main surface portion 51a disposed facing main surface portion 47 and extending in the width direction of power generation portion 24. Furthermore, magnet holding unit 50 includes rotating shaft portion 52 extending along the rotation axis of arm unit 40 and at least partially protruding from main surface portion 47 toward main surface portion 51a, and arm unit 40 includes insertion portion 48 into which rotating shaft portion 52 is inserted.

Thus, the use of rotating shaft portion 52 as the rotation axis (center of rotation) allows magnet holding unit 50 to easily rotate. Accordingly, the operability of power generation switch 10 further improves.

Furthermore, arm unit 40 includes main surface portion 47 extending in the width direction of power generation portion 24, and magnet holding unit 50 includes main surface portion 51a disposed facing main surface portion 47 and extending in the width direction of power generation portion 24. Furthermore, arm unit 40 includes rotating shaft portion 52 extending along the rotation axis of arm unit 40 and at least partially protruding from main surface portion 51a toward main surface portion 47, and magnet holding unit 50 includes insertion portion 48 into which rotating shaft portion 52 is inserted.

Thus, the use of rotating shaft portion 52 as the rotation axis (center of rotation) allows magnet holding unit 50 to easily rotate. Accordingly, the operability of power generation switch 10 further improves.

Furthermore, insertion portion 48 is configured to allow rotating shaft portion 52 to move inside insertion portion 48 in the Z-axis direction.

With this, the area of contact between insertion portion 48 and rotating shaft portion 52 can be reduced, and thus it is possible to reduce the resistance force due to friction that is applied to rotating shaft portion 52 upon rotation of rotating shaft portion 52 relative to arm unit 40. In other words, it is possible to reduce damage to rotating shaft portion 52 and keep rotating shaft portion 52 from following the tilting of arm unit 40. Accordingly, the operability of power generation switch 10 further improves.

Furthermore, rotating shaft portion 52 includes cutout portion 52a obtained by cutting off an end of rotating shaft portion 52 that faces insertion portion 48 when viewed in the width direction of power generation portion 24.

With this, rotating shaft potion 52 can be easily inserted into insertion portion 48, and thus the workability for inserting rotating shaft portion 52 into insertion portion 48 improves.

Furthermore, arm unit 40 includes: end portion 40a pivoted on first projection 22; and end portion 40b which moves in the Z-axis direction by rotation toward an area in the Z-axis direction.

This allows power generation switch 10 to be also applied to a power generation switch in which power generation portion 24 is bent through rotation of arm unit 40 to generate electric power.

Furthermore, power generation portion 24 includes two piezoelectric elements 24e, 24f and metal plate 24d. Two piezoelectric elements 24e, 24f are disposed at opposite sides of metal plate 24d.

With this, the amount of electric power that is generated by free vibrations of power generation portion 24 is greater than that in the case where there is one piezoelectric element.

### Other Exemplary Embodiments

Although power generation switch 10 according to an exemplary embodiment has been described on the basis of the exemplary embodiment, the present disclosure is not limited to said exemplary embodiment.

Thus, the structural elements set forth in the accompanying drawings and detailed description include not only structural elements essential to solve the problems but also structural elements unnecessary to solve the problems for the purpose of illustrating the above techniques. Thus, those unnecessary structural elements should not be deemed essential due to the mere fact that they appear in the accompanying drawings and the detailed description.

For example, although the above exemplary embodiment describes an example where when power generation switch 10 is operated, a lighting device is turned on, the number of electrical devices that are controlled by operation of power generation switch 10 is not limited to one. In a control device, a plurality of electrical devices to be controlled may be set for the identification information of power generation switch 10. For example, in the control device, the identification information of power generation switch 10 and the control for turning on a lighting device and the control for opening an electric curtain may be stored in association with each other. With these, it is possible to control a plurality of electrical devices such as the lighting device and the electric curtain by operating power generation switch 10 only once.

Furthermore, although the above exemplary embodiment describes an example where power generation switch 10 transmits a predetermined signal every time power generation switch 10 is operated, the operation of power generation switch 10 is not limited to the signal transmission. For example, power generation switch 10 may perform operations such as light or sound emission or may perform other operations every time power generation switch 10 is operated. This means that there is no limitation on usage of electric power generated when power generation switch 10 is operated.

Furthermore, although the above exemplary embodiment describes an example where power generation switch 10 is a portable switch, this is not limiting. For example, power generation switch 10 may be used for a switch that is fixed to a building material, such as a wall switch.

Furthermore, although the above exemplary embodiment describes an example where the shape of power generation switch 10 in a plan view is a substantially rectangular shape with four round corners, the shape of power generation switch 10 in a plan view is not limited to said shape. The shape of power generation switch 10 in a plan view may be substantially triangular, substantially trapezoidal, or substantially oval, or may be another shape. With this, in the case where two or more users use respective power generation switches 10, the shape of power generation switch 10 can be different for each user, for example; thus, it is possible to improve the usability of power generation switch 10.

Furthermore, although the above exemplary embodiment describes an example where when button unit 11 is pressed down, arm unit 40 rotates around first projection 22 as a rotation axis, the movement of arm unit 40 is not limited to rotation. For example, arm unit 40 may move parallel to an orientation in which button unit 11 is pressed down. In the example according to the above exemplary embodiment, when button unit 11 is pressed down, arm unit 40 may be pushed down in the negative direction of the Z-axis. Note that the meaning of the movement of arm unit 40 in the Z-axis direction includes the rotation of arm unit 40 to an area in the Z-axis direction as described in the above exemplary embodiment and pushing down of arm unit 40 substantially parallel to a direction parallel to the Z-axis.

Furthermore, although the above exemplary embodiment describes an example where one end (specifically, fixed end portion 24a) of power generation portion 24 is fixed to holder portion 21d, the position at which power generation portion 24 is fixed is not limited as long as desired electric power is successfully generated by vibrations of free end portion 24b. For example, power generation portion 24 may be fixed to holder portion 21d at a point in the middle in the Y-axis direction. In this case, the middle of power generation portion 24 is an example of the fixed portion which is fixed to holder portion 21d. Note that power generation portion 24 may be fixed at another position.

Furthermore, although the above exemplary embodiment describes an example where the shape of power generation portion 24 in a plan view is substantially rectangular, this is not limiting. The shape of power generation portion 24 is not limited as long as desired electric power is successfully generated by vibrations of free end portion 24b. For example, in power generation portion 24, free end portion 24b may be less in width than fixed end portion 24a. In other words, the shape of power generation portion 24 in a plan view may be substantially trapezoidal or may be another shape. Note that in this case, the line connecting fixed end portion 24a and free end portion 24b is, for example, the line connecting the middle of fixed end portion 24a in the X-axis direction and the middle of free end portion 24b in the X-axis direction.

Furthermore, although the above exemplary embodiment describes an example where magnet holding portion 50 is rotatably held by arm unit 40 in vibration generation unit 30, this is not limiting. For example, lever unit 70 may include: a moving unit which rotates when pushed down by button unit 11; and a pressing unit which rotates to push down arm unit 40, and the pressing unit may be rotatably held by the moving unit. With this, even when a point on the fixed end portion 24a side of button unit 11 is pressed down, magnet 60 can be pushed down while remaining in the parallel state.

Furthermore, although the above exemplary embodiment describes an example where power generation portion 24 includes magnetic plate 25, this is not limiting. For example, in the case where metal plate 24d is formed of a magnetic metal material, metal plate 24d can concurrently function as magnetic plate 25, and thus power generation portion 24 is not required to include magnetic plate 25. This allows a reduction in the number of components in power generation portion 24.

Furthermore, although the above exemplary embodiment describes an example where magnet holding unit 50 holds magnet 60 and magnetic plate 25 is disposed in power generation portion 24, this is not limiting. For example, magnet 60 may be disposed in power generation portion 24, and magnet holding unit 50 may hold magnetic plate 25. For example, magnet 60 may be disposed to concurrently function as a weight for power generation portion 24. In this case, magnet holding unit 50 including magnetic plate 25 is an example of the attracting unit.

Forms obtained by various modifications to the exemplary embodiment that can be conceived by a person having ordinary skill in the art as well as forms realized by arbitrarily combining structural elements and functions in the exemplary embodiment which are within the scope of the essence of the present disclosure are included in the present disclosure.

### INDUSTRIAL APPLICABILITY

The power generation switch according to the present disclosure can be used as a switch including a power generation device and is useful as a portable power generation switch or the like.

### REFERENCE MARKS IN THE DRAWINGS

10 power generation switch

11 button unit

11a upper surface portion

11b, 12b, 92 side surface portion

12 casing unit

12a bottom surface portion

13, 13a, 13b screw

20 power generation unit

21 holding portion

21a, 21c, 24c, 27a, 27b, 27c screw hole

21d holder portion

22, 46 first projection

23 second projection

24 power generation portion

24a fixed end portion

24b free end portion

24d metal plate

24e, 24f piezoelectric element

24g, 24i electrode

24h piezoelectric body

25 magnetic plate

26 signaling portion

26a substrate

26b shielding case

27 rigid plate

28 screw holder portion

30 vibration generation unit

40 arm unit (moving unit)

40a end portion (first end portion)

40b end portion (second end portion)

41a, 41b, 71a, 71b arm

42 connecting portion

43, 74 first opening

44, 75 second opening

45 third opening

47 main surface portion (first main surface portion)

48 insertion portion

48a claw portion

48b side wall portion

48c upper wall portion

50 magnet holding unit (attracting unit)

51 body portion

51a main surface portion (second main surface portion)

51b standing portion

52a cutout portion

52b, 76 projection

52 rotating shaft portion

53 holding portion

53a, 92a claw portion

60 magnet (attracting unit)

70 lever unit

72 first connecting portion

73 second connecting portion

77 curved portion

80 cover unit

81 opening

90 lower button unit

91 top plate

100 power generation device

1. A power generation switch, comprising:
a moving unit including at least a part that moves in a first direction; and
a power generation device which generates electric power through movement of the moving unit, wherein
the power generation device includes:
an attracting unit which moves in the first direction through the movement of the moving unit, the attracting unit including a magnet extending in a second direction perpendicular to the first direction;
a holder portion located in a third direction relative to the magnet, the third direction being perpendicular to the second direction; and
a power generation portion which includes a free end portion and a fixed portion and generates electric power by free vibrations of the free end portion, the power generation portion having a plate shape, the free end portion being placed in a state of attraction to the magnet and a state of release from the state of attraction, the fixed portion being fixed to the holder portion, and
the attracting unit is rotatably held by the moving unit.

2. The power generation switch according to claim 1, wherein
a rotation axis of the attracting unit is parallel to the third direction.

3. The power generation switch according to claim 2, wherein
the moving unit includes a first main surface portion extending in the second direction,
the attracting unit includes a second main surface portion disposed facing the first main surface portion and extending in the second direction,
the attracting unit includes a first shaft portion extending along the rotation axis and at least partially protruding from the second main surface portion toward the first main surface portion, and
the moving unit includes an insertion portion into which the first shaft portion is inserted.

4. The power generation switch according to claim 2, wherein
the moving unit includes a first main surface portion extending in the second direction,
the attracting unit includes a second main surface portion disposed facing the first main surface portion and extending in the second direction,
the moving unit includes a first shaft portion extending along the rotation axis and at least partially protruding from the first main surface portion toward the second main surface portion, and
the attracting unit includes an insertion portion into which the first shaft portion is inserted.

5. The power generation switch according to claim 3, wherein
the insertion portion is configured to allow the first shaft portion to move inside the insertion portion in the first direction.

6. The power generation switch according to claim 3, wherein
the first shaft portion includes a cutout portion, the cutout portion being obtained by cutting off an end of the first shaft portion that faces the insertion portion when viewed in the second direction.

7. The power generation switch according to claim 1, wherein
the moving unit includes: a first end portion pivoted on a second shaft portion; and a second end portion which moves in the first direction by rotation.

8. The power generation switch according to claim 1, wherein
the power generation portion includes two piezoelectric elements and a metal plate, and
the two piezoelectric elements are disposed at opposite sides of the metal plate.
